(19) United States
(12) Patent Application Publication
(10) Pub. No.: US 2025/0116930 A1
(43) Pub. Date: Apr. 10, 2025

(54) PHOTOSENSITIVE RESIN COMPOSITION, PHOTOSENSITIVE ELEMENT, PRINTED CIRCUIT BOARD, AND METHOD FOR MANUFACTURING PRINTED CIRCUIT BOARD

(71) Applicant: Resonac Corporation, Tokyo (JP)

(72) Inventors: Naomitsu KOMORI, Tokyo (JP); Shuji NOMOTO, Tokyo (JP); Akihiro NAKAMURA, Tokyo (JP); Yuta DAIJIMA, Tokyo (JP)

(21) Appl. No.: 18/687,180

(22) PCT Filed: Jan. 18, 2023
(86) PCT No.: PCT/JP2023/001376

§ 371 Date: Feb. 27, 2024

(30) Foreign Application Priority Data
Jan. 19, 2022 (WO) PCT/JP2022/001804

(51) Int. Cl. G03F 7/038; H05K 3/46

(52) U.S. Cl. CPC G03F 7/038; H05K 3/4644

(57) ABSTRACT

A photosensitive resin composition for a permanent resist according to the present disclosure contains an acid-modified vinyl group-containing resin (A), a thermosetting resin (B), a photopolymerization initiator (C), a photopolymerizable compound (D), and an elastomer (H), the photopolymerizable compound includes a photopolymerizable compound having an isocyanuric skeleton, and the elastomer includes a liquid elastomer or a granular elastomer having an average particle size of less than 4 μm.

### TECHNICAL FIELD

The present disclosure relates to a photosensitive resin composition for a permanent resist, a photosensitive element, a printed circuit board, and a method for manufacturing a printed circuit board.

### BACKGROUND ART

In the field of a printed circuit board, a permanent resist is formed on the printed circuit board. The permanent resist has a function of preventing the corrosion of a conductor layer or retaining electrical insulating properties between the conductor layers when the printed circuit board is used. Recently, even in a step of performing flip-chip packaging, wire bonding packaging, or the like of a semiconductor element on the printed circuit board via solder, the permanent resist also has a function as a solder resist film, which prevents the solder from being attached to an unnecessary portion of the conductor layer of the printed circuit board.

In the related art, the permanent resist is prepared by a method of performing screen printing using a thermosetting resin composition, or a photographic method using a photosensitive resin composition. For example, in a flexible wiring plate using a packaging method such as flip chip (FC), tape automated bonding (TAB), or chip on film (COF), the thermosetting resin paste is screen-printed except for an IC chip, an electronic component, a liquid crystal display (LCD) panel, and a connection wiring pattern portion, and thermally cured to form the permanent resist (for example, refer to Patent Literature 1).

In a semiconductor package substrate such as a ball grid array (BGA) or a chip size package (CSP), which is mounted on the electronic component, in order to (1) perform flip-chip packaging of the semiconductor element on the semiconductor package substrate via solder, (2) perform wire bonding of the semiconductor element and the semiconductor package substrate, and (3) perform solder bonding of the semiconductor package substrate on a motherboard substrate, it is necessary to remove the permanent resist in the bonding portion. In the image formation of the permanent resist, the photographic method is used in which the photosensitive resin composition is applied and dried, and then, cured by being selectively irradiated with an active light ray such as an ultraviolet ray, and only the unirradiated portion is removed by development to form an image. Since the photographic method has excellent workability and is suitable for mass production, the method is widely used in the image formation of a photosensitive material, in the industry of an electronic material (for example, refer to Patent Literature 2).

Recently, in response to an increase in the density of the printed circuit board, the permanent resist has been also required to further improve performance, and it has been important to improve properties such as fine pattern formation properties, thermal resistance, thermal shock resistance, adhesiveness, and insulating properties.

In order to improve the thermal resistance, the thermal shock resistance, and the adhesiveness of the permanent resist, it has been considered to form the permanent resist by using a photosensitive resin composition containing a carboxy group-containing resin, at least one of talc and mica, difunctional or higher (meth)acrylate having an isocyanuric ring, an epoxy resin, and a photopolymerization initiator (for example, refer to Patent Literature 3).

### CITATION LIST

### Patent Literature

Patent Literature 1: JP 2003-198105 A
Patent Literature 2: JP 2011-133851 A
Patent Literature 3: JP 2020-204774 A

### SUMMARY OF INVENTION

### Technical Problem

When forming a fine pattern with the photosensitive resin composition containing an amorphous inorganic filler such as talc and mica, it may be difficult to obtain a sufficient resolution. Since there is a trade-off relationship between the resolution and the thermal shock resistance, the photosensitive resin composition for a permanent resist is required to make the resolution, the thermal resistance, the thermal shock resistance, and the adhesiveness highly compatible.

An object of the present disclosure is to provide a photosensitive resin composition that has excellent resolution and is capable of forming a permanent resist excellent in thermal shock resistance, thermal resistance, and adhesiveness, and a photosensitive element, a printed circuit board, and a method for manufacturing a printed circuit board using the photosensitive resin composition described above.

### Solution to Problem

One aspect of the present disclosure relates to a photosensitive resin composition for a permanent resist, containing: an acid-modified vinyl group-containing resin (A), a thermosetting resin (B), a photopolymerization initiator (C), a photopolymerizable compound (D), and an elastomer (H), in which the photopolymerizable compound includes a photopolymerizable compound having an isocyanuric skeleton, and the elastomer includes a liquid elastomer or a granular elastomer having an average particle size of less than 4 μm.

Another aspect of the present disclosure relates to a photosensitive element, including: a support film; and a photosensitive layer formed on the support film, in which the photosensitive layer contains the photosensitive resin composition described above.

Another aspect of the present disclosure relates to a printed circuit board, including a permanent resist containing a cured material of the photosensitive resin composition described above.

Another aspect of the present disclosure relates to a method for manufacturing a printed circuit board, including a step of forming a photosensitive layer on a substrate by using the photosensitive resin composition or the photosensitive element described above; a step of forming a resist pattern by exposing and developing the photosensitive layer; and a step of forming a permanent resist by curing the resist pattern.

### Advantageous Effects of Invention

According to the present disclosure, it is possible to provide the photosensitive resin composition that has excellent resolution and is capable of forming the permanent resist excellent in the thermal shock resistance, the thermal resistance, and the adhesiveness, and the photosensitive element, the printed circuit board, and the method for manufacturing a printed circuit board using the photosensitive resin composition described above.

### BRIEF DESCRIPTION OF DRAWINGS

FIG. 1 is a sectional view schematically illustrating a photosensitive element according to this embodiment.

### DESCRIPTION OF EMBODIMENTS

The contents of a photosensitive resin composition according to an embodiment of the present disclosure, and a photosensitive element, a printed circuit board, and a method for manufacturing a printed circuit board using the photosensitive resin composition described above will be listed below.

[1] A photosensitive resin composition for a permanent resist, containing an acid-modified vinyl group-containing resin (A), a thermosetting resin (B), a photopolymerization initiator (C), a photopolymerizable compound (D), and an elastomer (H), in which the photopolymerizable compound includes a photopolymerizable compound having an isocyanuric skeleton, and the elastomer includes a liquid elastomer or a granular elastomer having an average particle size of less than 4 μm.

[2] The photosensitive resin composition according to [1] described above, in which the photopolymerizable compound having an isocyanuric skeleton is at least one type selected from the group consisting of isocyanuric acid-modified di(meth)acrylate and isocyanuric acid-modified tri(meth)acrylate.

[3] The photosensitive resin composition according to [1] or [2] described above, in which a content of the photopolymerizable compound is 1 to 15% by mass, on the basis of a total solid content in the photosensitive resin composition.

[4] The photosensitive resin composition according to any one of [1] to [3] described above, in which the thermosetting resin includes at least one type selected from the group consisting of a bisphenol A-type epoxy resin, a bisphenol F-type epoxy resin, a novolac-type epoxy resin, and an epoxy resin having an isocyanuric skeleton.

[5] The photosensitive resin composition according to any one of [1] to [4] described above, further containing an inorganic filler (E).

[6] The photosensitive resin composition according to any one of [1] to [5] described above, further containing an ion scavenger (G).

[7] A photosensitive element, including a support film and a photosensitive layer formed on the support film, in which the photosensitive layer contains the photosensitive resin composition according to any one of [1] to [6] described above.

[8] A printed circuit board, including a permanent resist containing a cured material of the photosensitive resin composition according to any one of [1] to [6] described above.

[9] A method for manufacturing a printed circuit board, including: a step of forming a photosensitive layer on a substrate by using the photosensitive resin composition according to any one of [1] to [6] described above or the photosensitive element according to [7] described above; a step of forming a resist pattern by exposing and developing the photosensitive layer; and a step of forming a permanent resist by curing the resist pattern.

Hereinafter, the present disclosure will be described in detail. In this specification, the term “step” includes not only an independent step but also a step that is not explicitly distinguishable from other steps insofar as a desired function of the step is attained. The term “layer” includes not only a structure in which a layer is formed on the entire surface but also a structure in which a layer is formed on a part of the surface when observed as a plan view. A numerical range represented by using “to” indicates a range including numerical values described before and after “to” as the minimum value and the maximum value, respectively. In numerical ranges described in stages in this specification, the upper limit value or the lower limit value of a numerical range in a certain stage may be replaced with the upper limit value or the lower limit value of a numerical range in the other stage. In the numerical range described in this specification, the upper limit value or the lower limit value of the numerical range may be replaced with values described in Examples.

In this specification, in a case where there are a plurality of substances corresponding to each component in a composition, unless otherwise specified, the amount of each component in the composition indicates the total amount of the plurality of substances in the composition.

In this specification, “(meth)acrylate” indicates at least one of “acrylate” and “methacrylate” corresponding thereto, and the same applies to other similar expressions such as a (meth)acrylic acid and (meth)acryloyl. In this specification, a “solid content” indicates a non-volatile content excluding a volatile substance (water, a solvent, or the like) contained in a photosensitive resin composition, and also includes a component in the shape of liquid, starch syrup, or wax at a room temperature (approximately 25° C.). Here, the liquid indicates having fluidity at a normal temperature and a normal pressure (1 atm, 25° C.).

### [Photosensitive Resin Composition]

A photosensitive resin composition for a permanent resist according to this embodiment contains an acid-modified vinyl group-containing resin (A), a thermosetting resin (B), a photopolymerization initiator (C), a photopolymerizable compound (D), and an elastomer (H), the photopolymerizable compound includes a photopolymerizable compound having an isocyanuric skeleton, and the elastomer includes a liquid elastomer or a granular elastomer having an average particle size of less than 4 μm. The photosensitive resin composition according to this embodiment is a negative photosensitive resin composition, and a cured film of the photosensitive resin composition can be used as a permanent resist. Hereinafter, each component used in the photosensitive resin composition of this embodiment will be described in more detail.

### (Component (A): Acid-Modified Vinyl Group-Containing Resin)

The photosensitive resin composition according to this embodiment contains the acid-modified vinyl group-containing resin as a component (A). The acid-modified vinyl group-containing resin is not particularly limited insofar as having a vinyl bond that is a photopolymerizable ethylenically unsaturated bond and an alkali-soluble acidic group.

Examples of the group having an ethylenically unsaturated bond in the component (A) include a vinyl group, an allyl group, a propargyl group, a butenyl group, an ethynyl group, a phenyl ethynyl group, a maleimide group, a nadimide group, and a (meth)acryloyl group. Among them, the (meth)acryloyl group is preferable from the viewpoint of reactivity and a resolution. Examples of the acidic group in the component (A) include a carboxy group, a sulfo group, and a phenolic hydroxyl group. Among them, the carboxy group is preferable from the viewpoint of the resolution.

It is preferable that the component (A) is an acid-modified vinyl group-containing epoxy derivative obtained by allowing a saturated group or unsaturated group-containing polybasic acid anhydride (c) (hereinafter, may be referred to as a “component (c)”.) to react with a resin (A′) obtained by a reaction between an epoxy resin (a) (hereinafter, may be referred to as a “component (a)”.) and an ethylenically unsaturated group-containing organic acid (b) (hereinafter, may be referred to as a “component (b)”.).

Examples of the acid-modified vinyl group-containing epoxy derivative include acid-modified epoxy (meth)acrylate. The acid-modified epoxy (meth)acrylate is a resin obtained by acid-modifying epoxy (meth)acrylate, which is a reactant of the component (a) and the component (b), with the component (c). As the acid-modified epoxy (meth)acrylate, for example, an esterified material obtained by a reaction between an epoxy resin and a vinyl group-containing monocarboxylic acid, and an additive reactant to which a saturated or unsaturated polybasic acid anhydride is added can be used.

Examples of the component (A) include an acid-modified vinyl group-containing resin (A1) (hereinafter, may be referred to as a “component (A1)”.) obtained by using a bisphenol novolac-type epoxy resin (a1) (hereinafter, may be referred to as an “epoxy resin (a1)”.) as the component (a), and an acid-modified vinyl group-containing resin (A2) (hereinafter, may be referred to as a “component (A2)”.) obtained by using an epoxy resin (a2) other than the epoxy resin (a1) (hereinafter, may be referred to as an “epoxy resin (a2)”.) as the component (a).

Examples of the epoxy resin (a1) include an epoxy resin having a structural unit represented by Formula (I) or (II) described below.

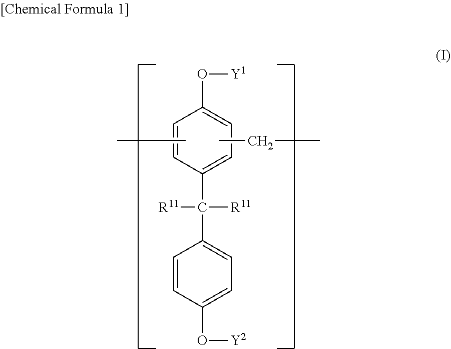

In Formula (I), R¹¹ represents a hydrogen atom or a methyl group, and a plurality of R¹¹s may be the same or different from each other. Y¹ and Y² each independently represent a hydrogen atom or a glycidyl group, and at least one of Y¹ and Y² is a glycidyl group. It is preferable that R¹¹ is a hydrogen atom from the viewpoint of suppressing the occurrence of undercut, and improving the linearity of a resist pattern contour and the resolution, and it is preferable that Y¹ and Y² are a glycidyl group from the viewpoint of further improving thermal shock resistance.

The number of structural units represented by Formula (I) in the epoxy resin (a1) is 1 or more, and may be 10 to 100, 15 to 80, or 15 to 70. In a case where the number of structural units is in the range described above, the linearity of the resist pattern contour, adhesiveness with a copper substrate, thermal resistance, and electrical insulating properties are easily improved. Here, the number of structural units indicates an integer value in a single molecule, and indicates a rational number that is an average value in the aggregate of a plurality of types of molecules. Hereinafter, the same applies to the number of structural units.

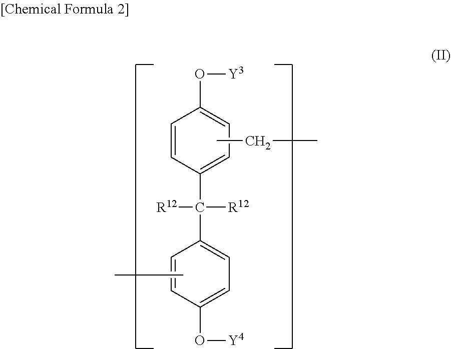

In Formula (II), R¹² represents a hydrogen atom or a methyl group, and a plurality of R¹²s may be the same or different from each other. Y³ and Y⁴ each independently represent a hydrogen atom or a glycidyl group, and at least one of Y³ and Y⁴ is a glycidyl group. It is preferable that R¹² is a hydrogen atom from the viewpoint of suppressing the occurrence of the undercut, and improving the linearity of the resist pattern contour and the resolution, and it is preferable that Y³ and Y⁴ are a glycidyl group from the viewpoint of further improving the thermal shock resistance.

The number of structural units represented by Formula (II) in the epoxy resin (a1) is 1 or more, and may be 10 to 100, 15 to 80, or 15 to 70. In a case where the number of structural units is in the range described above, the linearity of the resist pattern contour, the adhesiveness with the copper substrate, and the thermal resistance are easily improved.

In Formula (II), an epoxy resin in which R¹² is a hydrogen atom, and Y³ and Y⁴ are a glycidyl group is commercially available as EXA-7376 Series (manufactured by DIC Corporation, product name), and an epoxy resin in which R¹² is a methyl group, and Y³ and Y⁴ are a glycidyl group is commercially available as EPON SU8 Series (manufactured by Mitsubishi Chemical Corporation, product name).

The epoxy resin (a2) is not particularly limited insofar as the epoxy resin is different from the epoxy resin (a1), and is preferably at least one type selected from the group consisting of a novolac-type epoxy resin, a bisphenol A-type epoxy resin, a bisphenol F-type epoxy resin, a triphenol methane-type epoxy resin, and a biphenyl-type epoxy resin, from the viewpoint of suppressing the occurrence of the undercut, and improving the linearity of the resist pattern contour, the adhesiveness with the copper substrate, and the resolution.

Examples of the novolac-type epoxy resin include an epoxy resin having a structural unit represented by Formula (III) described below. Examples of the bisphenol A-type epoxy resin or the bisphenol F-type epoxy resin include an epoxy resin having a structural unit represented by Formula (IV) described below. Examples of the triphenol methane-type epoxy resin include an epoxy resin having a structural unit represented by Formula (V) described below. Examples of the biphenyl-type epoxy resin include an epoxy resin having a structural unit represented by Formula (VI) described below.

As the epoxy resin (a2), a novolac-type epoxy resin having a structural unit represented by Formula (III) described below is preferable. Examples of the novolac-type epoxy resin having such a structural unit include a novolac-type epoxy resin represented by Formula (III′) described below.

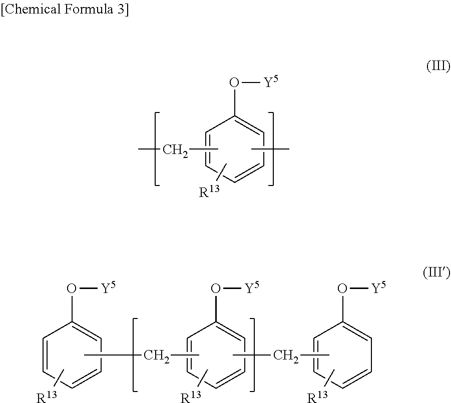

In Formulae (III) and (III′), R¹³ represents a hydrogen atom or a methyl group, Y⁵ represents a hydrogen atom or a glycidyl group, and at least one Y⁵ is a glycidyl group. In Formula (III′), n₁ is a number of 1 or more, and a plurality of R¹³s and Y⁵s may be the same or different from each other. It is preferable that R¹³ is a hydrogen atom from the viewpoint of suppressing the occurrence of the undercut, and improving the linearity of the resist pattern contour and the resolution.

In Formula (III′), a molar ratio between Y⁵ that is a hydrogen atom and Y⁵ that is a glycidyl group may be 0/100 to 30/70, or 0/100 to 10/90, from the viewpoint of suppressing the occurrence of the undercut, and improving the linearity of the resist pattern contour and the resolution. n₁ is 1 or more, and may be 10 to 200, 30 to 150, or 30 to 100. In a case where n₁ is in the range described above, the linearity of the resist pattern contour, the adhesiveness with the copper substrate, and the thermal resistance are easily improved.

Examples of the novolac-type epoxy resin represented by Formula (III′) include a phenol novolac-type epoxy resin and a cresol novolac-type epoxy resin. Such a novolac-type epoxy resin, for example, can be obtained by a reaction between a phenol novolac resin or a cresol novolac resin and epichlorohydrin in accordance with a known method.

As the phenol novolac-type epoxy resin or the cresol novolac-type epoxy resin represented by Formula (III′), for example, YDCN-701, YDCN-702, YDCN-703, YDCN-704, YDCN-704L, YDPN-638, and YDPN-602 (which are manufactured by NIPPON STEEL Chemical & Material Co., Ltd., product name), DEN-431 and DEN-439 (which are manufactured by The Dow Chemical Company, product name), EOCN-120, EOCN-102S, EOCN-103S, EOCN-104S, EOCN-1012, EOCN-1025, EOCN-1027, and BREN (which are manufactured by Nippon Kayaku Co., Ltd., product name), EPN-1138, EPN-1235, and EPN-1299 (which are manufactured by BASF, product name), N-730, N-770, N-865, N-665, N-673, VH-4150, and VH-4240 (which are manufactured by DIC Corporation, product name), and the like are commercially available.

Examples of the epoxy resin (a2) preferably include a bisphenol A-type epoxy resin or a bisphenol F-type epoxy resin having a structural unit represented by Formula (IV) described below. Examples of the epoxy resin having such a structural unit include a bisphenol A-type epoxy resin or a bisphenol F-type epoxy resin represented by Formula (IV′) described below.

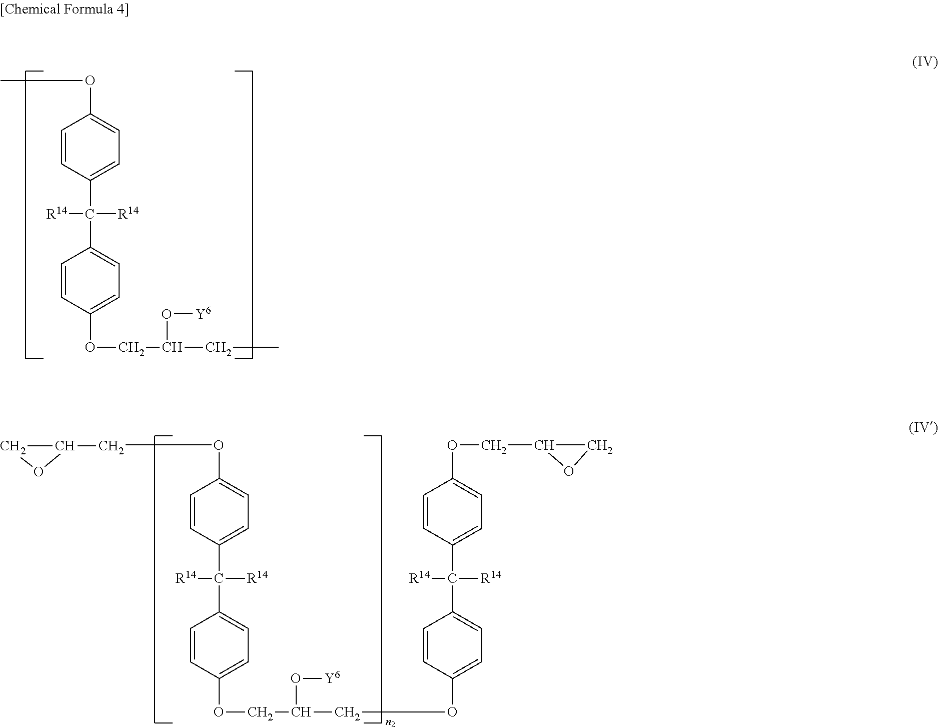

In Formulae (IV) and (IV′), R¹⁴ represents a hydrogen atom or a methyl group, a plurality of R¹⁴s may be the same or different from each other, and Y⁶ represents a hydrogen atom or a glycidyl group. In Formula (IV′), n₂ is a number of 1 or more, and in a case where n₂ is 2 or more, a plurality of Y's may be the same or different from each other, and at least one Y⁶ is a glycidyl group.

It is preferable that R¹⁴ is a hydrogen atom from the viewpoint of suppressing the occurrence of the undercut, and improving the linearity of the resist pattern contour and the resolution, and it is preferable that Y⁶ is a glycidyl group from the viewpoint of further improving the thermal shock resistance. n₂ represents 1 or more, and may be 10 to 100, 10 to 80, or 15 to 60. In a case where n₂ is in the range described above, the linearity of the resist pattern contour, the adhesiveness with the copper substrate, and the thermal resistance are easily improved.

A bisphenol A-type epoxy resin or a bisphenol F-type epoxy resin in which Y⁶ in Formula (IV) is a glycidyl group, for example, can be obtained by a reaction between a hydroxyl group (—OY⁶) of a bisphenol A-type epoxy resin or a bisphenol F-type epoxy resin in which Y⁶ in Formula (IV) is a hydrogen atom and epichlorohydrin.

In order to accelerate the reaction between the hydroxyl group and the epichlorohydrin, it is preferable to perform the reaction in a polar organic solvent such as dimethyl formamide, dimethyl acetamide, and dimethyl sulfoxide at a reaction temperature of 50 to 120° C. in the presence of an alkali metal hydroxide. In a case where the reaction temperature is in the range described above, the reaction is not excessively slowed down, and an adverse reaction can be suppressed.

As the bisphenol A-type epoxy resin or the bisphenol F-type epoxy resin represented by Formula (IV′), for example, jER807, jER815, jER825, jER827, jER828, jER834, jER1001, jER1004, jER1007, and jER1009 (which are manufactured by Mitsubishi Chemical Corporation, product name), DER-330, DER-301, and DER-361 (which are manufactured by The Dow Chemical Company, product name), YD-8125, YDF-170, YDF-175S, YDF-2001, YDF-2004, and YDF-8170 (which are manufactured by NIPPON STEEL Chemical & Material Co., Ltd., product name), and the like are commercially available.

Examples of the epoxy resin (a2) preferably include a triphenol methane-type epoxy resin having a structural unit represented by Formula (V) described below. Examples of the triphenol methane-type epoxy resin having such a structural unit include a triphenol methane-type epoxy resin represented by Formula (V′) described below.

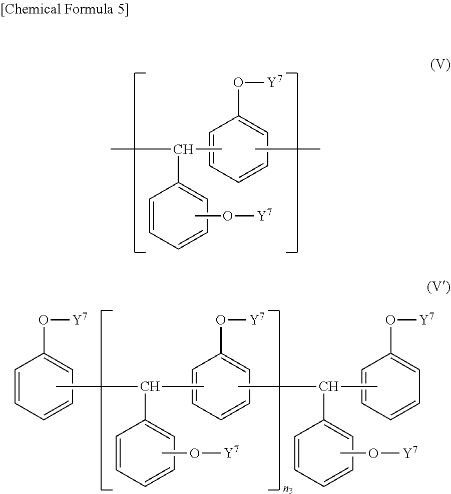

In Formulae (V) and (V′), Y⁷ represents a hydrogen atom or a glycidyl group, a plurality of Y⁷s may be the same or different from each other, and at least one Y⁷ is a glycidyl group. In Formula (V′), n₃ represents a number of 1 or more.

A molar ratio between Y⁷ that is a hydrogen atom and Y⁷ that is a glycidyl group in Y⁷ may be 0/100 to 30/70 from the viewpoint of suppressing the occurrence of the undercut and upper omission, and improving the linearity of the resist pattern contour and the resolution. As can be seen from such a molar ratio, at least one Y⁷ is a glycidyl group. n₃ is 1 or more, and may be 10 to 100, 15 to 80, or 15 to 70. In a case where n₃ is in the range described above, the linearity of the resist pattern contour, the adhesiveness with the copper substrate, and the thermal resistance are easily improved.

As the triphenol methane-type epoxy resin represented by Formula (V′), for example, FAE-2500, EPPN-501H, and EPPN-502H (which are manufactured by Nippon Kayaku Co., Ltd., product name), and the like are commercially available.

Examples of the epoxy resin (a2) preferably include a biphenyl-type epoxy resin having a structural unit represented by Formula (VI) described below. Examples of the biphenyl-type epoxy resin having such a structural unit include a biphenyl-type epoxy resin represented by Formula (VI′) described below.

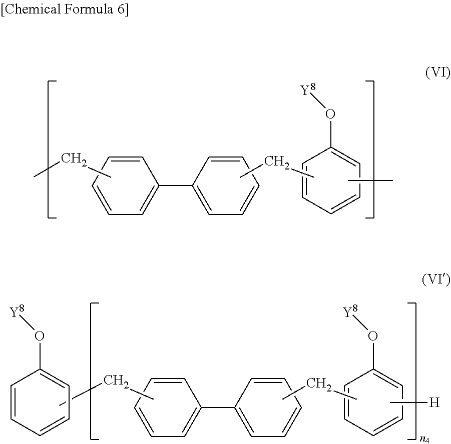

In Formulae (VI) and (VI′), Y⁸ represents a hydrogen atom or a glycidyl group, a plurality of Y's may be the same or different from each other, and at least one Y⁸ is a glycidyl group. In Formula (V′), n₄ represents a number of 1 or more.

As the biphenyl-type epoxy resin represented by Formula (VI′), for example, NC-3000, NC-3000-L, NC-3000-H, NC-3000-FH-75M, NC-3100, and CER-3000-L (which are manufactured by Nippon Kayaku Co., Ltd., product name), and the like are commercially available.

As the epoxy resin (a2), at least one type selected from the group consisting of the novolac-type epoxy resin having the structural unit represented by Formula (III), the bisphenol A-type epoxy resin having the structural unit represented by Formula (IV), and the bisphenol F-type epoxy resin having the structural unit represented by Formula (IV) is preferable, and the bisphenol F-type epoxy resin having the structural unit represented by Formula (IV) is more preferable.

The component (A1) using the bisphenol novolac-type epoxy resin having the structural unit represented by Formula (II) as the epoxy resin (a1), and the component (A2) using the bisphenol A-type epoxy resin or the bisphenol F-type epoxy resin having the structural unit represented by Formula (IV) as the epoxy resin (a2) may be used in combination from the viewpoint of further improving the thermal shock resistance, warpage reduction, and the resolution.

Examples of the component (b) include an acrylic acid derivative such as an acrylic acid, a dimer of an acrylic acid, a methacrylic acid, a β-furfuryl acrylic acid, a β-styryl acrylic acid, a cinnamic acid, a crotonic acid, and a α-cyanocinnamic acid; a half-ester compound that is a reaction product of hydroxyl group-containing (meth)acrylate and a dibasic acid anhydride; and a half-ester compound that is a reaction product of vinyl group-containing monoglycidyl ether or vinyl group-containing monoglycidyl ester and a dibasic acid anhydride. Only one type of component (b) may be used alone, or two or more types thereof may be used in combination.

The half-ester compound, for example, can be obtained by a reaction between hydroxyl group-containing (meth)acrylate, vinyl group-containing monoglycidyl ether, or vinyl group-containing monoglycidyl ester, and a dibasic acid anhydride.

Examples of the hydroxyl group-containing (meth)acrylate, the vinyl group-containing monoglycidyl ether, and the vinyl group-containing monoglycidyl ester include hydroxyethyl (meth)acrylate, hydroxypropyl (meth)acrylate, hydroxybutyl (meth)acrylate, polyethylene glycol trimethylol propane di(meth)acrylate, pentaerythritol tri(meth)acrylate, dipentaerythritol penta(meth)acrylate, and glycidyl (meth)acrylate.

Examples of the dibasic acid anhydride include a succinic anhydride, a maleic anhydride, a tetrahydrophthalic anhydride, a phthalic anhydride, a methyl tetrahydrophthalic anhydride, an ethyl tetrahydrophthalic anhydride, a hexahydrophthalic anhydride, a methyl hexahydrophthalic anhydride, an ethyl hexahydrophthalic anhydride, and an itaconic anhydride.

In the reaction between the component (a) and the component (b), it is preferable to perform the reaction at a ratio where the component (b) is 0.6 to 1.05 equivalents to 1 equivalent of the epoxy group of the component (a), and it is more preferable to perform the reaction at a ratio where the component (b) is 0.8 to 1.0 equivalents. By performing the reaction at such a ratio, there is a tendency that optical sensitivity increases, and the linearity of the resist pattern contour is excellent.

The component (a) and the component (b) can be dissolved in an organic solvent to react with each other. Examples of the organic solvent include ketones such as methyl ethyl ketone and cyclohexanone; aromatic hydrocarbon such as toluene, xylene, and tetramethyl benzene; glycol ethers such as methyl cellosolve, butyl cellosolve, methyl carbitol, butyl carbitol, propylene glycol monomethyl ether, dipropylene glycol monoethyl ether, dipropylene glycol diethyl ether, and triethylene glycol monoethyl ether; esters such as ethyl acetate, butyl acetate, butyl cellosolve acetate, and carbitol acetate; aliphatic hydrocarbon such as octane and decane; and a petroleum-based solvent such as petroleum ether, petroleum naphtha, hydrogenated petroleum naphtha, and solvent naphtha. Only one type of organic solvent may be used alone, or two or more types thereof may be used in combination.

A catalyst for accelerating the reaction between the component (a) and the component (b) may be used. Examples of the catalyst include triethyl amine, benzyl methyl amine, methyl triethyl ammonium chloride, benzyl trimethyl ammonium chloride, benzyl trimethyl ammonium bromide, benzyl trimethyl ammonium iodide, and triphenyl phosphine. Only one type of catalyst may be used alone, or two or more types thereof may be used in combination.

The amount of catalyst used may be 0.01 to 10 parts by mass, 0.05 to 2 parts by mass, or 0.1 to 1 part by mass, with respect to a total of 100 parts by mass of the component (a) and the component (b), from the viewpoint of accelerating the reaction between the component (a) and the component (b).

In the reaction between the component (a) and the component (b), a polymerization inhibitor may be used to prevent polymerization during the reaction. Examples of the polymerization inhibitor include hydroquinone, methyl hydroquinone, hydroquinone monomethyl ether, catechol, and pyrogallol. Only one type of polymerization inhibitor may be used alone, or two or more types thereof may be used in combination.

The amount of polymerization inhibitor used may be 0.01 to 1 part by mass, 0.02 to 0.8 parts by mass, or 0.04 to 0.5 parts by mass, with respect to a total of 100 parts by mass of the component (a) and the component (b), from the viewpoint of improving stability.

The reaction temperature of the component (a) and the component (b) may be 60 to 150° C., 80 to 120° C., or 90 to 110° C., from the viewpoint of productivity.

The component (A′) obtained by the reaction between the component (a) and the component (b) has a hydroxyl group formed by a ring-opening addition reaction between the epoxy group of the component (a) and the carboxy group of the component (b). By allowing the component (c) to further react with the component (A′), the acid-modified vinyl group-containing resin is obtained in which the hydroxyl group (also including the hydroxyl group originally existing in the component (a)) of the component (A′) and the acid anhydride group of the component (c) are half-esterified.

Examples of the component (c) include a succinic anhydride, a maleic anhydride, a tetrahydrophthalic anhydride, a phthalic anhydride, a methyl tetrahydrophthalic anhydride, an ethyl tetrahydrophthalic anhydride, a hexahydrophthalic anhydride, a methyl hexahydrophthalic anhydride, an ethyl hexahydrophthalic anhydride, and an itaconic anhydride. Among them, the tetrahydrophthalic anhydride is preferable from the viewpoint of the resolution. Only one type of component (c) may be used alone, or two or more types thereof may be used in combination.

In the reaction between the component (A′) and the component (c), for example, by allowing 0.1 to 1.0 equivalent of the component (c) to react with 1 equivalent of the hydroxyl group in the component (A′), it is possible to adjust the acid value of the component (A).

The reaction temperature of the component (A′) and the component (c) may be 50 to 150° C., 60 to 120° C., or 70 to 100° C., from the viewpoint of the productivity.

As necessary, as the component (a), a hydrogenated bisphenol A-type epoxy resin may be partially used together, or a styrene-maleic acid-based resin such as modified hydroxyethyl (meth)acrylate of a styrene-maleic anhydride copolymer may be partially used together.

It is preferable that the component (A) includes the component (A1) from the viewpoint of suppressing the occurrence of the undercut, and further improving the adhesiveness with the copper substrate, the thermal shock resistance, and the resolution, and it is more preferable that the component (A) includes the component (A1) and the component (A2) particularly from the viewpoint of improving an adhesive strength.

In a case where the component (A1) and the component (A2) are used in combination as the component (A), a mass ratio of (A1)/(A2) is not particularly limited, and may be 20/80 to 90/10, 30/70 to 80/20, 40/60 to 75/25, or 50/50 to 70/30, from the viewpoint of improving the linearity of the resist pattern contour, electroless plating resistance, and the thermal resistance.

The acid value of the component (A) is not particularly limited. The acid value of the component (A) may be 30 mgKOH/g or more, 40 mgKOH/g or more, or 50 mgKOH/g or more, from the viewpoint of improving the solubility of the unexposed portion with respect to an alkaline solution. The acid value of the component (A) may be 150 mgKOH/g or less, 120 mgKOH/g or less, or 100 mgKOH/g or less, from the viewpoint of improving the electrical properties of the cured film.

A weight average molecular weight (Mw) of the component (A) is not particularly limited. Mw of the component (A) may be 3000 or more, 4000 or more, or 5000 or more, from the viewpoint of improving the adhesiveness of the cured film. Mw of the component (A) may be 30000 or less, 25000 or less, or 18000 or less, from the viewpoint of improving the resolution of the photosensitive layer.

Mw can be measured by a gel permeation chromatography (GPC) method. Mw, for example, can be measured in the following GPC condition, and a value converted by using a calibration curve of standard polystyrene can be Mw. In the creation of the calibration curve, a set of five samples (“PStQuick MP-H” and “PStQuick B”, manufactured by Tosoh Corporation) can be set as the standard polystyrene.
GPC device: a high-speed GPC device “HCL-8320GPC” (manufactured by Tosoh Corporation)
Detector: a differential refractometer or a UV detector (manufactured by Tosoh Corporation)
Column: a column TSKgel SuperMultipore HZ-H (column length: 15 cm, column inner diameter: 4.6 mm) (manufactured by Tosoh Corporation)
Eluent: tetrahydrofuran (THF)
Measurement temperature: 40° C.
Flow rate: 0.35 mL/minute
Sample concentration: 10 mg/THF 5 mL
Injected amount: 20 μL

The content of the component (A) in the photosensitive resin composition may be 20 to 70% by mass, 25 to 60% by mass, or 30 to 50% by mass, on the basis of the total solid content of the photosensitive resin composition, from the viewpoint of improving the thermal resistance, the electrical properties, and the chemical resistance of the permanent resist.

### (Component (B): Thermosetting Resin)

In the photosensitive resin composition according to this embodiment, by using the thermosetting resin as the component (B), it is possible to improve the thermal resistance, the adhesion properties, and the chemical resistance of the cured film (the permanent resist) formed of the photosensitive resin composition. Only one type of component (B) may be used alone, or two or more types thereof may be used in combination.

Examples of the component (B) include an epoxy resin, a phenolic resin, an unsaturated imide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, and a melamine resin.

Examples of the epoxy resin include a bisphenol A-type epoxy resin, a bisphenol F-type epoxy resin, a hydrogenated bisphenol A-type epoxy resin, a brominated bisphenol A-type epoxy resin, a bisphenol S-type epoxy resin, a novolac-type epoxy resin, a biphenyl-type epoxy resin, a naphthalene-type epoxy resin, a dicyclopentadiene-type epoxy resin, a hydantoin-type epoxy resin, an epoxy resin having an isocyanuric skeleton, and a bixylenol-type epoxy resin.

From the viewpoint of further improving the thermal resistance of the permanent resist, it is preferable that the component (B) includes the epoxy resin, and it is more preferable that the component (B) includes at least one type selected from the group consisting of the bisphenol A-type epoxy resin, the bisphenol F-type epoxy resin, the novolac-type epoxy resin, and the epoxy resin having an isocyanuric skeleton.

The content of the component (B) may be 2 to 30% by mass, 4 to 25% by mass, 6 to 20% by mass, or 8 to 15% by mass, on the basis of the total solid content of the photosensitive resin composition. In a case where the content of the component (B) is in the range described above, it is possible to further improve the thermal resistance of the cured film to be formed while maintaining excellent development properties.

### (Component (C): Photopolymerization Initiator)

The photopolymerization initiator that is the component (C) is not particularly limited insofar as the component (A) and the component (D) can be polymerized. Only one type of component (C) may be used alone, or two or more types thereof may be used in combination.

Examples of the component (C) include a benzoin compound such as benzoin, benzoin methyl ether, and benzoin isopropyl ether; an acetophenone compound such as acetophenone, 2,2-dimethoxy-2-phenyl acetophenone, 2,2-diethoxy-2-phenyl acetophenone, 1,1-dichloroacetophenone, 1-hydroxycyclohexyl phenyl ketone, 2-benzyl-2-dimethyl amino-1-(4-morpholinophenyl)-butanone-1, 2-methyl-[4-(methyl thio)phenyl]-2-morpholino-1-propane, and N,N-dimethyl aminoacetophenone; an anthraquinone compound such as 2-methyl anthraquinone, 2-ethyl anthraquinone, 2-tert-butyl anthraquinone, 1-chloroanthraquinone, 2-amyl anthraquinone, and 2-aminoanthraquinone; a thioxanthone compound such as 2,4-dimethyl thioxanthone, 2,4-diethyl thioxanthone, 2-chlorothioxanthone, and 2,4-diisopropyl thioxanthone; a ketal compound such as acetophenone dimethyl ketal and benzyl dimethyl ketal; a benzophenone compound such as benzophenone, methyl benzophenone, 4,4′-dichlorobenzophenone, 4,4′-bis(diethyl amino)benzophenone, Michler's ketone, and 4-benzoyl-4′-methyl diphenyl sulfide; an imidazole compound such as a 2-(o-chlorophenyl)-4,5-diphenyl imidazole dimer, a 2-(o-chlorophenyl)-4,5-di(m-methoxyphenyl) imidazole dimer, a 2-(o-fluorophenyl)-4,5-diphenyl imidazole dimer, a 2-(o-methoxyphenyl)-4,5-diphenyl imidazole dimer, a 2-(p-methoxyphenyl)-4,5-diphenyl imidazole dimer, a 2,4-di(p-methoxyphenyl)-5-phenyl imidazole dimer, and a 2-(2,4-dimethoxyphenyl)-4,5-diphenyl imidazole dimer; an acridine compound such as 9-phenyl acridine and 1,7-bis(9,9′-acridinyl) heptane; an acyl phosphine oxide compound such as 2,4,6-trimethyl benzoyl diphenyl phosphine oxide; an oxime ester compound such as 1,2-octane dione-1-[4-(phenyl thio)phenyl]-2-(O-benzoyl oxime), 1-[9-ethyl-6-(2-methyl benzoyl)-9H-carbazol-3-yl]ethanone 1-(O-acetyl oxime), and 1-phenyl-1,2-propane dione-2-[O-(ethoxycarbonyl) oxime]; and a tertiary amine compound such as N,N-dimethyl aminobenzoic acid ethyl ester, N,N-dimethyl aminobenzoic acid isoamyl ester, pentyl-4-dimethyl aminobenzoate, triethyl amine, and triethanol amine.

The content of the component (C) in the photosensitive resin composition is not particularly limited, and may be 0.2 to 15% by mass, 0.5 to 10% by mass, 0.8 to 5% by mass, or 1 to 3% by mass, on the basis of the total solid content of the photosensitive resin composition.

### (Component (D): Photopolymerizable Compound)

The component (D) is a compound that has a photopolymerizable ethylenically unsaturated bond but does not have an acidic group. The group having an ethylenically unsaturated bond is not particularly limited insofar as the group has photopolymerizability. Examples of the group having an ethylenically unsaturated bond include a vinyl group, an allyl group, a propargyl group, a butenyl group, an ethynyl group, a phenyl ethynyl group, a maleimide group, a nadimide group, and a (meth)acryloyl group. From the viewpoint of the reactivity and the resolution, it is preferable that the component (D) has the (meth)acryloyl group. Only one type of component (D) may be used alone, or two or more types thereof may be used in combination.

In the photosensitive resin composition according to this embodiment, by using the photopolymerizable compound having an isocyanuric skeleton as the component (D), it is possible to improve the resolution of the photosensitive resin composition, and form the permanent resist excellent in the thermal resistance, the thermal shock resistance, and the adhesiveness.

It is preferable that the photopolymerizable compound having an isocyanuric skeleton is at least one type selected from the group consisting of isocyanuric acid-modified di(meth)acrylate and isocyanuric acid-modified tri(meth)acrylate. Examples of the photopolymerizable compound having an isocyanuric skeleton include ethoxylated isocyanuric acid di(meth)acrylate, ethoxylated isocyanuric acid tri(meth)acrylate, propoxylated isocyanuric acid di(meth)acrylate, and propoxylated isocyanuric acid tri(meth)acrylate.

The component (D) may further include a photopolymerizable compound not having an isocyanuric skeleton. Examples of the photopolymerizable compound not having an isocyanuric skeleton include a hydroxyalkyl (meth)acrylate compound such as 2-hydroxyethyl (meth)acrylate and 2-hydroxypropyl (meth)acrylate; a mono- or di(meth)acrylate compound of glycol such as ethylene glycol, methoxytetraethylene glycol, and polyethylene glycol; a (meth)acrylamide compound such as N,N-dimethyl (meth)acrylamide and N-methylol (meth)acrylamide; an aminoalkyl (meth)acrylate compound such as N,N-dimethyl aminoethyl (meth)acrylate; a (meth)acrylate compound of polyhydric alcohol such as hexanediol, trimethylol propane, pentaerythritol, ditrimethylol propane, and dipentaerythritol; a (meth)acrylate compound having an aromatic ring such as phenoxyethyl (meth)acrylate and polyethoxydi(meth)acrylate; a (meth)acrylate compound of glycidyl ether such as glycerine diglycidyl ether and trimethylol propane triglycidyl ether; and melamine (meth)acrylate. It is preferable that the molecular weight of the photopolymerizable compound not having an isocyanuric skeleton is 1000 or less from the viewpoint of the optical sensitivity.

In order to further improve the thermal resistance by increasing a cross-linking density with photo-curing, as the component (D), a photopolymerizable compound having three or more ethylenically unsaturated bonds may be used. The component (D) may further include dipentaerythritol tri(meth)acrylate from the viewpoint of further improving sensitivity.

The content of the component (D) in the photosensitive resin composition of this embodiment may be 1 to 15% by mass, 2 to 12% by mass, 3 to 10% by mass, or 4 to 8% by mass, on the basis of the total solid content of the photosensitive resin composition, from the viewpoint of forming the permanent resist excellent in the thermal resistance and the thermal shock resistance while exhibiting a higher resolution and an excellent resist pattern shape. In a case where the content of the component (D) is 1% by mass or more, the optical sensitivity is improved, and the exposed portion is less likely to be eluted during development, and in a case where the content is 15% by mass or less, the thermal resistance of the permanent resist is easily improved.

The content of the photopolymerizable compound having an isocyanuric skeleton is preferably 1 to 15% by mass, more preferably 2 to 12% by mass, and even more preferably 4 to 10% by mass, on the basis of the total solid content of the photosensitive resin composition, from the viewpoint of further improving the adhesiveness, the thermal resistance, and the thermal shock resistance of the permanent resist.

### (Component (H): Elastomer)

In the photosensitive resin composition according to this embodiment, by containing an elastomer as a component (H), it is possible to suppress a decrease in flexibility and an adhesion strength caused by strain (an inner stress) in the resin due to the curing shrinkage of the component (A).

Examples of the component (H) include a styrene-based elastomer, an olefin-based elastomer, a urethane-based elastomer, a polyester-based elastomer, a polyamide-based elastomer, an acrylic elastomer, and a silicone-based elastomer. Such an elastomer is composed of a hard segment component, which contributes to the thermal resistance and the strength, and a soft segment component, which contributes to softness and toughness. Among them, the olefin-based elastomer and the polyester-based elastomer are preferable.

Examples of the styrene-based elastomer include a styrene-butadiene-styrene block copolymer, a styrene-isoprene-styrene block copolymer, a styrene-ethylene-butylene-styrene block copolymer, and a styrene-ethylene-propylene-styrene block copolymer. As a component configuring the styrene-based elastomer, a styrene derivative such as α-methyl styrene, 3-methyl styrene, 4-propyl styrene, and 4-cyclohexyl styrene can be used, in addition to styrene.

Examples of the olefin-based elastomer include an ethylene-propylene copolymer, an ethylene-α-olefin copolymer, an ethylene-α-olefin-non-conjugated diene copolymer, a propylene-α-olefin copolymer, a butene-α-olefin copolymer, an ethylene-propylene-diene copolymer, a copolymer of non-conjugated diene and α-olefin such as dicyclopentadiene, 1,4-hexadiene, cyclooctadiene, methylene norbornene, ethylidene norbornene, butadiene, and isoprene, epoxy-modified polybutadiene, and a carboxylic acid-modified butadiene-acrylonitrile copolymer.

The epoxy-modified polybutadiene has preferably a hydroxyl group on a molecular end, more preferably a hydroxyl group on both molecular ends, and even more preferably a hydroxyl group only on both molecular ends. The number of hydroxyl groups in the epoxy-modified polybutadiene may be 1 or more, preferably 1 to 5, more preferably 1 or 2, and even more preferably 2.

As the urethane-based elastomer, a compound composed of a hard segment consisting of low molecular (short-chain) diol and diisocyanate, and a soft segment consisting of high molecular (long-chain) diol and diisocyanate can be used.

Examples of the short-chain diol include ethylene glycol, propylene glycol, 1,4-butanediol, and bisphenol A. It is preferable that the number average molecular weight of the short-chain diol is 48 to 500.

Examples of the long-chain diol include polypropylene glycol, polytetramethylene oxide, poly(1,4-butylene adipate), poly(ethylene-1,4-butylene adipate), polycaprolactone, poly(1,6-hexylene carbonate), and poly(1,6-hexylene-neopentylene adipate). It is preferable that the number average molecular weight of the long-chain diol is 500 to 10000.

As the polyester-based elastomer, a compound (for example, a polyester resin) can be used in which a dicarboxylic acid or a derivative thereof and a diol compound or a derivative thereof are polycondensed.

Examples of the dicarboxylic acid include an aromatic dicarboxylic acid such as a terephthalic acid, an isophthalic acid, and a naphthalene dicarboxylic acid; an aliphatic dicarboxylic acid having 2 to 20 carbon atoms such as an adipic acid, a sebacic acid, and a dodecane dicarboxylic acid; and an alicyclic dicarboxylic acid such as a cyclohexane dicarboxylic acid. Only one type of dicarboxylic acid can be used alone, or two or more types thereof can be used in combination.

Examples of the diol compound include aliphatic diol such as ethylene glycol, 1,3-propanediol, 1,4-butanediol, 1,6-hexanediol, and 1,10-decanediol; alicyclic diol such as 1,4-cyclohexanediol; and aromatic diol such as bisphenol A, bis-(4-hydroxyphenyl) methane, bis-(4-hydroxy-3-methyl phenyl) propane, and resorcin.

As the polyester-based elastomer, a multiblock copolymer using aromatic polyester (for example, polybutylene terephthalate) as a hard segment component and aliphatic polyester (for example, polytetramethylene glycol) as a soft segment component can be used. There are various grades of polyester-based elastomers, in accordance with a difference in the types, the ratios, and the molecular weights of the hard segment and the soft segment.

The polyamide-based elastomer is broadly divided into two types of polyether block amide and polyether ester block amide using polyamide as a hard segment and polyether or polyester as a soft segment. Examples of the polyamide include polyamide-6, polyamide-11, and polyamide-12. Examples of the polyether include polyoxyethylene glycol, polyoxypropylene glycol, and polytetramethylene glycol.

In the acrylic elastomer, a compound having a constitutional group based on (meth)acrylic acid ester as a main component can be used. Examples of the (meth)acrylic acid ester include methyl (meth)acrylate, ethyl (meth)acrylate, butyl (meth)acrylate, methoxyethyl (meth)acrylate, and ethoxyethyl (meth)acrylate. The acrylic elastomer may be a compound in which (meth)acrylic acid ester and acrylonitrile are copolymerized, or may be a compound in which a monomer having a functional group to be a cross-linking point is further copolymerized. Examples of the monomer having a functional group include glycidyl methacrylate and allyl glycidyl ether.

Examples of the acrylic elastomer include an acrylonitrile-butyl acrylate copolymer, an acrylonitrile-butyl acrylate-ethyl acrylate copolymer, a methyl methacrylate-butyl acrylate-methacrylic acid copolymer, and an acrylonitrile-butyl acrylate-glycidyl methacrylate copolymer. As the acrylic elastomer, the acrylonitrile-butyl acrylate-glycidyl methacrylate copolymer or the methyl methacrylate-butyl acrylate-methacrylic acid copolymer is preferable, and the methyl methacrylate-butyl acrylate-methacrylic acid copolymer is more preferable.

The silicone-based elastomer is a compound containing organopolysiloxane as a main component. Examples of the organopolysiloxane include polydimethyl siloxane, polymethyl phenyl siloxane, and polydiphenyl siloxane. The silicone-based elastomer may be a compound in which a part of the organopolysiloxane is modified with a vinyl group, an alkoxy group, or the like. The silicone-based elastomer may be a granular silicone-based elastomer such as acrylic silicone composite rubber and a silicone composite powder.

The component (H) may include the carboxylic acid-modified butadiene-acrylonitrile copolymer or the polyester-based elastomer having a hydroxyl group from the viewpoint of improving the adhesiveness of the cured film.

Since the elastomer component (H) includes the liquid elastomer or the granular elastomer having an average particle size of less than 4 μm, it is possible to improve the resolution of the photosensitive resin composition, and form the permanent resist having an excellent resist pattern shape.

The liquid elastomer is not particularly limited insofar as being liquid and having fluidity at a normal temperature and a normal pressure. As the liquid elastomer, an olefin-based elastomer such as epoxy-modified polybutadiene, or a polyester-based elastomer such as a polyester resin may be used.

The granular elastomer is solid at a normal temperature and a normal pressure. The average particle size of the granular elastomer is less than 4 μm, 3.8 μm or less, and may be 3.5 μm or less, or 3.0 μm or less, from the viewpoint of further improving the resolution. The lower limit value of the average particle size of the granular elastomer may be 0.1 μm or more, 0.4 μm or more, or 0.6 μm or more, from the viewpoint of preventing a decrease in preservation stability. The average particle size indicates an average particle size obtained from a volume-average particle size distribution measurement results measured by a laser diffraction particle size analyzer. As the granular elastomer, a silicone-based elastomer such as acrylic silicone composite rubber and a silicone composite powder may be used.

The content of the component (H) may be 2 parts by mass or more, 4 parts by mass or more, 6 parts by mass or more, 10 parts by mass or more, or 15 parts by mass or more, and may be 40 parts by mass or less, 30 parts by mass or less, 25 parts by mass or less, 20 parts by mass or less, or 15 parts by mass, with respect to 100 parts by mass of the component (A). The content of the component (H) may be 2 to 40 parts by mass, 4 to 30 parts by mass, 6 to 25 parts by mass, 6 to 20 parts by mass, 10 to 20 parts by mass, or 10 to 15 parts by mass, with respect to 100 parts by mass of the component (A). In a case where the content of the component (H) is in the range described above, the elastic modulus of the cured film in a high-temperature region decreases, and the unexposed portion is easily eluted by a developer. The content of the component (H) may be 1 to 25% by mass, 3 to 20% by mass, 5 to 15% by mass, or 5 to 10% by mass, on the basis of the total solid content of the photosensitive resin composition.

### (Component (E): Inorganic Filler)

The photosensitive resin composition according to this embodiment may further contain an inorganic filler as a component (E). By containing the component (E), it is possible to improve the adhesion strength and the hardness of the permanent resist. Only one type of component (E) may be used alone, or two or more types thereof may be used in combination.

Examples of the inorganic filler include silica, alumina, titania, tantalum oxide, zirconia, silicon nitride, barium titanate, barium carbonate, magnesium carbonate, aluminum hydroxide, magnesium hydroxide, lead titanate, lead zirconate titanate, lead lanthanum zirconate titanate, gallium oxide, spinel, mullite, cordierite, talc, aluminum titanate, yttria-containing zirconia, barium silicate, boron nitride, calcium carbonate, barium sulfate, calcium sulfate, zinc oxide, magnesium titanate, hydrotalcite, mica, calcined kaolin, and carbon.

The component (E) may include the silica from the viewpoint of improving the thermal resistance of the permanent resist, and may include the barium sulfate or may include the silica and the barium sulfate from the viewpoint of improving the thermal resistance and the adhesion strength of the permanent resist. An inorganic filler of which the surface is treated in advance with alumina or an organic silane compound may be used from the viewpoint of improving the dispersibility of the inorganic filler.

The average particle size of the inorganic filler may be 0.01 to 5.0 μm, 0.05 to 3.0 μm, 0.1 to 2.0 μm, or 0.15 to 1.0 μm, from the viewpoint of the resolution.

The average particle size of the component (E) is the average particle size of the inorganic filler in the state of being dispersed in the photosensitive resin composition, and is set as a value obtained by the following measurement. First, the photosensitive resin composition is diluted 1000 times with methyl ethyl ketone, and then, particles dispersed in a solvent are measured by using a submicron particle analyzer (manufactured by Beckman Coulter, Inc., product name “N5”) at a refractive index of 1.38, on the basis of International Organization for Standardization ISO13321, and a particle size at an integrated value 50% (volume basis) in a particle size distribution is set as an average particle size.

The content of the component (E) may be 5 to 70% by mass, 6 to 60% by mass, or 10 to 50% by mass, on the basis of the total solid content of the photosensitive resin composition. In a case where the content of the component (E) is in the range described above, a low-thermal expansion coefficient, the thermal resistance, and a film strength can be further improved.

In the case of using silica as the component (E), the content of the silica may be 5 to 60% by mass, 10 to 55% by mass, or 15 to 50% by mass, on the basis of the total solid content of the photosensitive resin composition. In the case of using barium sulfate as the component (E), the content of the barium sulfate may be 5 to 30% by mass, 5 to 25% by mass, or 10 to 20% by mass, on the basis of the total solid content of the photosensitive resin composition. In a case where the content of the silica and the barium sulfate is in the range described above, the low-thermal expansion coefficient, solder thermal resistance, and the adhesion strength tend to be excellent.

### (Component (F): Pigment)

The photosensitive resin composition according to this embodiment may further contain a pigment as a component (F), from the viewpoint of improving distinguishability or appearance. As the component (F), a colorant for producing a desired color when concealing wiring (a conductor pattern) can be used. Only one type of component (E) may be used alone, or two or more types thereof may be used in combination.

Examples of the component (F) include phthalocyanine blue, phthalocyanine green, iodine green, diazo yellow, crystal violet, titanium oxide, carbon black, and naphthalene black.

The content of the component (F) may be 0.01 to 5.0% by mass, 0.03 to 3.0% by mass, or 0.05 to 2.0% by mass, on the basis of the total solid content in the photosensitive resin composition, from the viewpoint of easily distinguishing a manufacturing apparatus and further concealing the wiring.

### (Component (G): Ion Scavenger)

The photosensitive resin composition according to this embodiment may further contain an ion scavenger as a component (G), from the viewpoint of improving a resist shape, the adhesiveness, the fluidity, and reliability. The component (G) is not particularly limited insofar as being capable of scavenging ions in the ion scavenger and having a function of scavenging at least one of cations and anions.

In this embodiment, the ions to be scavenged, for example, are ions such as sodium ions (Na⁺), chlorine ions (Cl⁻), bromine ions (Br⁻), and copper ions (Cu⁺, Cu²⁺), which are incorporated in a composition of which the degree of solubility with respect to a solvent is changed due to a reaction by the irradiation of light, an electron beam, or the like. By scavenging such ions, the electrical insulating properties, electrical corrosion resistance, and the like are improved.

It is preferable that the component (G) is an ion scavenger having at least one type selected from the group consisting of zirconium (Zr), bismuth (Bi), magnesium (Mg), and aluminum (Al). Only one type of component (G) may be used alone, or two or more types thereof may be used in combination.

Examples of the component (G) include a cation scavenger for scavenging cations, an anion scavenger for scavenging anions, and an ampholyte ion scavenger for scavenging cations and anions.

Examples of the cation scavenger include an inorganic ion exchanger of a metal oxide such as zirconium phosphate, zirconium tungstate, zirconium molybdate, zirconium tungstate, zirconium antimonate, zirconium selenate, zirconium tellurate, zirconium silicate, zirconium phosphosilicate, and polyzirconium phosphate.

Examples of the anion scavenger include an inorganic ion exchanger such as a bismuth oxide hydrate and hydrotalcites.

Examples of the ampholyte ion scavenger include an inorganic ion exchanger of an aqueous metal oxide such as an aluminum oxide hydrate and a zirconium oxide hydrate. As the ampholyte ion scavenger, IXE-1320 (a Mg,Al-containing compound), IXE-600 (a Bi-containing compound), IXE-633 (a Bi-containing compound), IXE-680 (a Bi-containing compound), IXE-6107 (a Zr,Bi-containing compound), IXE-6136 (a Zr,Bi-containing compound), IXEPLAS-A1 (a Zr,Mg,Al-containing compound), IXEPLAS-A2 (a Zr,Mg,Al-containing compound), and IXEPLAS-B1 (a Zr,Bi-containing compound), which are manufactured by TOAGOSEI CO., LTD., and the like are commercially available.

As the component (G), a granular component can be used, and the average particle size of the component (G) may be 5 μm or less, 3 μm or less, or 2 μm or less, or may be 0.1 μm or more, from the viewpoint of improving insulating properties. The average particle size of the component (G) is the particle size of the particles in the state of being dispersed in the photosensitive resin composition, and can be measured by the same method as the method for measuring the average particle size of the component (E).

In a case where the photosensitive resin composition of this embodiment contains the component (G), the content thereof is not particularly limited, and may be 0.05 to 10% by mass, 0.1 to 5% by mass, or 0.2 to 1% by mass, on the basis of the total solid content of the photosensitive resin composition, from the viewpoint of improving the electrical insulating properties and the electrical corrosion resistance.

### (Other Components)

The photosensitive resin composition according to this embodiment, as necessary, may further contain various additives. Examples of the additives include a polymerization inhibitor such as hydroquinone, methyl hydroquinone, hydroquinone monomethyl ether, catechol, and pyrogallol; a thickener such as BENTONE and montmorillonite; a silicone-based antifoaming agent, a fluorine-based antifoaming agent, and a vinyl resin-based antifoaming agent; a silane coupling agent; and a flame retardant such as a brominated epoxy compound, an acid-modified brominated epoxy compound, an antimony compound, a phosphate compound, aromatic condensed phosphoric acid ester, and halogen-containing condensed phosphoric acid ester.

### (Solvent)

In the photosensitive resin composition according to this embodiment, by containing a solvent for dissolving and dispersing each component, it is easy to apply the composition onto the substrate, and it is possible to form a coated film with a homogeneous thickness.

Examples of the solvent include ketone such as methyl ethyl ketone and cyclohexanone; aromatic hydrocarbon such as toluene, xylene, and tetramethyl benzene; glycol ether such as methyl cellosolve, butyl cellosolve, methyl carbitol, butyl carbitol, propylene glycol monomethyl ether, dipropylene glycol monoethyl ether, dipropylene glycol diethyl ether, and triethylene glycol monoethyl ether; ester such as ethyl acetate, butyl acetate, butyl cellosolve acetate, and carbitol acetate; aliphatic hydrocarbon such as octane and decane; and a petroleum-based solvent such as petroleum ether, petroleum naphtha, hydrogenated petroleum naphtha, and solvent naphtha. Only one type of solvent may be used alone, or two or more types thereof may be used in combination.

The blending amount of the solvent is not particularly limited, and the ratio of the solvent in the photosensitive resin composition may be 10 to 50% by mass, 20 to 40% by mass, or 25 to 35% by mass.

The photosensitive resin composition of this embodiment can be prepared by homogeneously mixing each component described above with a roll mill, a bead mill, or the like.

### [Photosensitive Element]

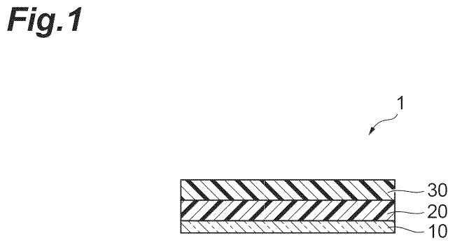

A photosensitive element according to this embodiment includes a support film, and a photosensitive layer containing the photosensitive resin composition described above. FIG. 1 is a sectional view schematically illustrating the photosensitive element according to this embodiment. As illustrated in FIG. 1, a photosensitive element 1 includes a support film 10, and a photosensitive layer 20 formed on the support film 10.

The photosensitive element 1 can be prepared by applying the photosensitive resin composition according to this embodiment onto the support film 10 with a known method such as reverse roll coating, gravure roll coating, comma coating, and curtain coating, and then, drying the coated film to form the photosensitive layer 20.

Examples of the support film include a polyester film such as polyethylene terephthalate and polybutylene terephthalate; and a polyolefin film such as polypropylene and polyethylene. The thickness of the support film, for example, may be 5 to 100 μm. The surface roughness of the support film is not particularly limited, and arithmetic mean roughness (Ra) may be 1000 nm or less, 500 nm or less, or 250 nm or less. The thickness of the photosensitive layer, for example, may be 5 to 50 μm, 5 to 40 μm, or 10 to 30 μm.

As the drying of the coated film, hot-air drying, or drying using a far-infrared ray or a near-infrared ray can be used. A drying temperature may be 60 to 120° C., 70 to 110° C., or 80 to 100° C. A drying time may be 1 to 60 minutes, 2 to 30 minutes, or 5 to 20 minutes.

On the photosensitive layer 20, a protective film 30 for covering the photosensitive layer 20 may be further provided. In the photosensitive element 1, the protective film 30 can also be laminated on the surface of the photosensitive layer 20 on a side opposite to the support film 10. As the protective film 30, for example, a polymer film such as polyethylene and polypropylene may be used.

### [Printed Circuit Board]

A printed circuit board according to this embodiment includes a permanent resist containing a cured material of the photosensitive resin composition according to this embodiment.

A method for manufacturing a printed circuit board according to this embodiment includes a step of forming a photosensitive layer on a substrate by using the photosensitive resin composition or the photosensitive element described above, a step of forming a resist pattern by exposing and developing the photosensitive layer, and a step of forming a permanent resist by curing the resist pattern. Hereinafter, an example of each step will be described.

First, the substrate such as a copper clad laminate is prepared, and the photosensitive layer is formed on the substrate. The photosensitive layer may be formed by applying the photosensitive resin composition onto the substrate and drying the composition. Examples of a method for applying the photosensitive resin composition include a screen printing method, a spraying method, a roll coating method, a curtain coating method, and an electrostatic coating method. A drying temperature may be 60 to 120° C., 70 to 110° C., or 80 to 100° C. A drying time may be 1 to 7 minutes, 1 to 6 minutes, or 2 to 5 minutes.

The photosensitive layer may be formed by peeling off the protective film from the photosensitive element and laminating the photosensitive layer on the substrate. Examples of a method for laminating the photosensitive layer include a method for performing thermal lamination using a laminator.

Next, a negative film is brought into contact with the photosensitive layer directly or via the support film, and irradiated with an active light ray to be exposed. Examples of the active light ray include an electron beam, an ultraviolet ray, and an X-ray, and the ultraviolet ray is preferable. As a light source, a low-pressure mercury lamp, a high-pressure mercury lamp, an ultrahigh-pressure mercury lamp, a halogen lamp, and the like can be used. An exposure amount may be 10 to 2000 mJ/cm², 100 to 1500 mJ/cm², or 300 to 1000 mJ/cm².

After exposure, the unexposed portion is removed with a developer to form the resist pattern. Examples of a development method include a dipping method and a spraying method. As the developer, for example, an alkaline solution such as potassium hydroxide, sodium hydroxide, sodium carbonate, potassium carbonate, and tetramethyl ammonium hydroxide can be used.

The resist pattern is subjected to at least one treatment of post-exposure and post-heating to form a patterned cured film (the permanent resist). The exposure amount of the post-exposure may be 100 to 5000 mJ/cm², 500 to 2000 mJ/cm², or 700 to 1500 J/cm². The heating temperature of the post-heating may be 100 to 200° C., 120 to 180° C., or 135 to 165° C. The heating time of the post-heating may be 5 minutes to 12 hours, 10 minutes to 6 hours, or 30 minutes to 2 hours.

A permanent resist according to this embodiment can be used as an interlayer insulating layer or a surface protective layer of the semiconductor element. It is possible to prepare a semiconductor element including the interlayer insulating layer or the surface protective layer formed of the cured film of the photosensitive resin composition described above, and an electronic device including the semiconductor element. The semiconductor element, for example, may be a memory, a package, or the like, having a multilayer wiring structure, a redistribution structure, or the like. Examples of the electronic device include a mobile phone, a smart phone, a tablet terminal, a personal computer, and a hard disk suspension. By including the patterned cured film formed of the photosensitive resin composition according to this embodiment, it is possible to provide the semiconductor element and the electronic device excellent in reliability.

### EXAMPLES

Hereinafter, the present disclosure will be described in more detail by examples, but the present invention is not limited to such examples.

### Synthesis Example 1

350 parts by mass of a bisphenol F novolac-type epoxy resin (manufactured by DIC Corporation, product name “EXA-7376”, a bisphenol F novolac-type epoxy resin having a structural unit in which in Formula (II), Y³ and Y⁴ are a glycidyl group, and R¹² is a hydrogen atom, epoxy equivalent: 186), 70 parts by mass of an acrylic acid, 0.5 parts by mass of methyl hydroquinone, and 120 parts by mass of carbitol acetate were mixed at 90° C. while stirring. The mixed liquid was cooled to 60° C., and 2 parts by mass of triphenyl phosphine was added thereto to react with each other until the acid value of the solution at 100° C. was 1 mgKOH/g or less. 98 parts by mass of a tetrahydrophthalic anhydride (THPAC) and 85 parts by mass of carbitol acetate were added to the reaction liquid to react with each other at 80° C. for 6 hours. After that, the reaction liquid was cooled to a room temperature, and a solution of acid-modified epoxy acrylate (A-1) as a component (A) (solid content concentration: 73% by mass) was obtained.

### Synthesis Example 2

1052 parts by mass of a bisphenol F-type epoxy resin (a bisphenol F-type epoxy resin having a structural unit in which in Formula (IV), Y⁶ is a hydrogen atom, and R¹⁴ is a hydrogen atom, epoxy equivalent: 526), 144 parts by mass of an acrylic acid, 1 part by mass of methyl hydroquinone, 850 parts by mass of carbitol acetate, and 100 parts by mass of solvent naphtha were mixed at 70° C. while stirring. The mixed liquid was cooled to 50° C., and 2 parts by mass of triphenyl phosphine and 75 parts by mass of solvent naphtha were added thereto to react with each other until the acid value of the solution at 100° C. was 1 mgKOH/g or less. The reaction liquid was cooled to 50° C., and then, 745 parts by mass of THPAC, 75 parts by mass of carbitol acetate, and 75 parts by mass of solvent naphtha were added thereto to react with each other at 80° C. for 6 hours. After that, the reaction solution was cooled to a room temperature, and a solution of acid-modified epoxy acrylate (A-2) as a component (A) (solid content concentration: 62% by mass) was obtained.

As the components (B) to (G), the following materials were prepared.
B-1: Tetramethyl bisphenol F-type epoxy resin (manufactured by NIPPON STEEL Chemical & Material Co., Ltd., product name “YSLV-80XY”)
B-2: Novolac-type polyfunctional epoxy resin (manufactured by Nippon Kayaku Co., Ltd., product name “RE-306”)
B-3: Epoxy resin having an isocyanuric acid structure (manufactured by Nissan Chemical Corporation, product name “TEPIC-FL”)
C-1:2-methyl-[4-(methyl thio) phenyl]morpholino-1-propanone (manufactured by IGM. Resins B.V., product name “Omirad 907”)
C-2:2,4-diethyl thioxanthone (manufactured by Nippon Kayaku Co., Ltd., product name “DETX-S”)
C-3:4,4′-bis(diethyl amino)benzophenone (EAB)
C-4: Ethanone, 1-[9-ethyl-6-(2-methyl benzoyl)-9H-carbazol-3-yl]-, 1-(0-acetyl oxime) (manufactured by BASF Japan Ltd., product name “Irgacure OXE02”)
D-1: Ethoxylated isocyanuric acid tri(meth)acrylate (manufactured by SHIN-NAKAMURA CHEMICAL Co., Ltd., product name “A-9300”)
D-2: Isocyanuric acid EO-modified di- and triacrylate (manufactured by TOAGOSEI CO., LTD., product name “M-313”)
D-3: Isocyanuric acid tris(2-acryloyl oxyethyl) (manufactured by Showa Denko Materials Co., Ltd., product name “FA-731A”)
D-4: Dipentaerythritol hexaacrylate (manufactured by Nippon Kayaku Co., Ltd., product name “DPHA”)
E-1: Silica (manufactured by Denka Company Limited, product name “SFP20M”, average particle size: 0.3 μm)
E-2: Barium sulfate (manufactured by SAKAI CHEMICAL INDUSTRY CO., LTD., product name “B-34”, average particle size: 0.3 μm)
F-1: Phthalocyanine green (manufactured by SANYO COLOR WORKS, Ltd.)
G-1: Zr, Mg, Al-based ampholyte ion scavenger (manufactured by TOAGOSEI CO., LTD., product name “IXEPLAS-A2”, average particle size: 0.2 μm, Content of Zr Compound: 20 to 30% by mass)
H-1: Epoxidized polybutadiene (manufactured by Daicel Corporation, product name “PB-3600”, a liquid elastomer)
H-2: Polyester resin (manufactured by Showa Denko Materials Co., Ltd., product name “SP1108”, a liquid elastomer)
H-3: Acrylic silicone composite rubber (manufactured by Mitsubishi Chemical Corporation, product name “METABLEN SX-005”, average particle size: 2 μm or less)
H-4: Silicone composite powder (manufactured by Shin-Etsu Chemical Co., Ltd., product name “X-52-7030”, average particle size: 0.8 μm)
H-5: Silicone composite powder (manufactured by Shin-Etsu Chemical Co., Ltd., product name “KMP-605”, average particle size: 2 μm)
H-6: Silicone composite powder (manufactured by Shin-Etsu Chemical Co., Ltd., product name “KMP-600”, average particle size: 5 μm)
H-7: Urethane beads in which a polyisocyanate prepolymer and polyol are polymerized (manufactured by Negami Chemical Industrial Co., Ltd., product name “ART PEARL C-800”, average particle size: 6 μm)
H-8: Cross-linking polymethyl methacrylate-based organic filler (manufactured by Aica Kogyo Company, Limited, product name “GM-0401S”, average particle size: 4 μm)
H-9: Core-shell type organic filler (a multiple structure in which the inner layer is acrylic rubber, the intermediate layer is covered with an epoxy resin, and a glass layer is formed on the outermost layer with silica, manufactured by Aica Kogyo Company, Limited, product name “Stafyroid”, average particle size: 8.1 μm)

### [Photosensitive Resin Composition]

Each component was blended at a blending amount (parts by mass, a solid content equivalent) shown in Table 1 or Table 2, and kneaded with a triple roll mill. After that, carbitol acetate was added such that the solid content concentration was 70% by mass, and a photosensitive resin composition was prepared.

### [Photosensitive Element]

As a support film, a polyethylene terephthalate film (manufactured by Toyobo Film Solutions Limited, product name “G2-25”) with a thickness of 25 μm was prepared. A solution obtained by diluting the photosensitive resin composition with methyl ethyl ketone was applied onto the support film such that the thickness after drying was 25 μm, and dried by using a hot-air convection drier at 75° C. for 30 minutes to form a photosensitive layer. Next, a polyethylene film (manufactured by TAMAPOLY CO., LTD., product name “NF-15”) was bonded as a protective film onto the surface of the photosensitive layer on a side opposite to a side in contact with the support film to obtain a photosensitive element.

### (Resolution)

A copper clad laminate substrate (manufactured by Showa Denko Materials Co., Ltd., product name “MCL-E-67”) with a thickness of 0.6 mm was prepared. While the protective film was peeled off from the photosensitive element to be removed, the photosensitive layer was laminated on the copper clad laminate substrate by using a press-type vacuum laminator (manufactured by MEIKI CO., LTD., product name “MVLP-500”) at a compression pressure of 0.4 MPa and a press heat plate temperature of 80° C. for a vacuum drawing time of 25 seconds and a laminating pressing time of 25 seconds to obtain a laminate. Next, a negative mask including an opening pattern with a predetermined size (opening diameter size: 30, 40, 50, 60, 70, 80, 90, 100, 110, 120, 150, and 200 μm) was allowed to adhere to a carrier film of the laminate, and the photosensitive layer was exposed by using an ultraviolet exposure device (manufactured by Oak Inc., product name “EXM-1201”) at an exposure amount where the number of completely curing stages in a step tablet (manufactured by Showa Denko Materials Co., Ltd.) is 13. After that, the carrier film was peeled off from the photosensitive layer, and spray development was performed by using an aqueous solution of sodium carbonate of 1% by mass at a pressure of 1.765× 10⁵ Pa for 60 seconds to dissolve and develop the unexposed portion. Next, the photosensitive layer after development was exposed by using an ultraviolet exposure device at an exposure amount of 2000 mJ/cm², and then, heated at 170° C. for 1 hour to prepare a test piece including a cured film in which the opening pattern with a predetermined size was formed on the copper clad laminate substrate. The test piece was observed with an optical microscope, and evaluated with the following criteria.
A: The minimum diameter of the mask to be opened was 35 μm or less.
B: The minimum diameter of the mask to be opened was greater than 35 μm and 55 μm or less.
C: The minimum diameter of the mask to be opened was greater than 55 μm.

### (Resist Pattern Shape)

The test piece was subjected to cast molding with an embedding resin (product name “jER828” manufactured by Mitsubishi Chemical Corporation was used as an epoxy resin, and triethylene tetramine was used as a curing agent), sufficiently cured, and then, polished with a polishing machine (manufactured by Refine Tec Ltd., product name “Refine Polisher”) to cut the sectional surface of the opening pattern of the cured film. The obtained sectional surface of the opening pattern was observed with a metal microscope, and evaluated with the following criteria.
A: The undercut and the upper omission of the resist were not checked, and the linearity of the pattern contour was excellent.
B: The undercut and the upper omission of the resist were checked, or the linearity of the pattern contour was poor.

### (Thermal Shock Resistance)

The test piece was subjected to a temperature cycle test at −65° C. for 30 minutes and 150° C. for 30 minutes as 1 cycle, and the test piece was observed visually and with an optical microscope at 1000 cycles and 2000 cycles, and evaluated with the following criteria.
A: The occurrence of the crack was not checked at 2000 cycles.
B: The occurrence of the crack was not checked at 1000 cycles, but the occurrence of the crack was checked at 2000 cycles.
C: The occurrence of the crack was checked at 1000 cycles.

### (Thermal Resistance)

The test piece was placed in the environment of 150° C., and the test piece was observed visually and with an optical microscope after 1000 hours and after 2000 hours, and evaluated with the following criteria.
A: The occurrence of the crack was not checked for 2000 hours.
B: The occurrence of the crack was not checked for 1000 hours, but the occurrence of the crack was checked for 2000 hours.
C: The occurrence of the crack was checked for 1000 hours.

### (Adhesiveness)

A copper foil (manufactured by Nippon Denkai, Ltd.) with a thickness of 35 μm was etched with a microetchant (manufactured by MEC Co., Ltd.) such that the etching amount was 1.0 μm. The copper foil after etching was washed with water, and the etched surface was subjected to a spray treatment with a hydrochloric acid of 3.5%, washed with water, and dried. Next, the photosensitive resin composition was applied onto the copper foil after the treatment by a screen printing method such that the thickness after drying was 20 μm, and dried by using a hot-air circulation drier at 75° C. for 30 minutes to form a photosensitive layer. Next, the negative mask was allowed to adhere to the photosensitive layer, and the photosensitive layer was exposed by using a parallel exposure machine (manufactured by HIGH-TECH CORPORATION, product name “HTE-5102S”) at an exposure amount of 100 mJ/cm². After that, spray development was performed with an aqueous solution of sodium carbonate of 1% by mass at a pressure of 1.765× 105 Pa for 60 seconds to dissolve and develop the unexposed portion. Next, exposure was performed by using an ultraviolet exposure device at an exposure amount of 2000 mJ/cm², and heating was performed at 170° C. for 1 hour to prepare a test piece in which a permanent resist was provided on the copper foil. The surface of the test piece on which the permanent resist was provided adhered to a copper clad laminate (manufactured by Showa Denko Materials Co., Ltd., product name “MCL-E-67”) with a bonding adhesive (manufactured by Konishi Co., Ltd., product name “Bond E Set”) to prepare a laminate.

The laminate was left to stand for 12 hours, and then, 10 mm of one end of the copper foil was peeled off, the laminate was fixed, the peeled copper foil was held with a chuck, a load (a peel strength) when performing peeling in the thickness direction (the vertical direction) of the copper foil at a pulling rate of 50 mm/minutes and a room temperature was measured 8 times, and the average value was calculated from eight measured values. The peel strength was evaluated on the basis of JIS C 5016 (1994-Peel Strength of Conductor), and evaluated with the following criteria.
A: The peel strength was greater than 0.5 N/mm.
B: The peel strength was in a range of 0.3 to 0.5 N/mm.
C: The peel strength was less than 0.3 N/mm.

TABLE 1

| Example | | 1 | 2 | 3 | 4 | 5 | 6 | 7 | 8 | 9 | 10 |
|---|---|---|---|---|---|---|---|---|---|---|---|
| (A) | A-1 | 21.5 | 21.5 | 21.5 | 21.5 | 21.5 | 21.5 | 21.5 | 21.5 | 21.5 | 21.5 |
| | A-2 | 15.0 | 10.0 | 10.0 | 15.0 | 12.0 | 15.0 | 15.0 | 15.0 | 15.0 | 15.0 |
| (B) | B-1 | 7.0 | 7.0 | 7.0 | 7.0 | 7.0 | — | — | 7.0 | 7.0 | 7.0 |
| | B-2 | 3.5 | 3.5 | 3.5 | 3.5 | 3.5 | 3.5 | 3.5 | 3.5 | 3.5 | 3.5 |
| | B-3 | — | — | — | — | — | 7.0 | 7.0 | — | — | — |
| (C) | C-1 | 0.9 | 0.9 | 0.9 | 0.9 | 0.9 | 0.9 | 0.9 | 0.9 | 0.9 | 0.9 |
| | C-2 | 0.1 | 0.1 | 0.1 | 0.1 | 0.1 | 0.1 | 0.1 | 0.1 | 0.1 | 0.1 |
| | C-3 | 0.1 | 0.1 | 0.1 | 0.1 | 0.1 | 0.1 | 0.1 | 0.1 | 0.1 | 0.1 |
| | C-4 | 0.1 | 0.1 | 0.1 | 0.1 | 0.1 | 0.1 | 0.1 | 0.1 | 0.1 | 0.1 |
| (D) | D-1 | — | — | — | 5.0 | 4.0 | — | — | — | — | — |
| | D-2 | 5.0 | 5.0 | 10.0 | — | 4.0 | 5.0 | — | 5.0 | 5.0 | 5.0 |
| | D-3 | — | — | — | — | — | — | 5.0 | — | — | — |
| | D-4 | — | 5.0 | — | — | — | — | — | — | — | — |
| (E) | E-1 | 28.0 | 28.0 | 28.0 | 28.0 | 28.0 | 28.0 | 28.0 | 28.0 | 28.0 | 28.0 |
| | E-2 | 10.0 | 10.0 | 10.0 | 10.0 | 10.0 | 10.0 | 10.0 | 10.0 | 10.0 | 10.0 |
| (F) | F-1 | 1.3 | 1.3 | 1.3 | 1.3 | 1.3 | 1.3 | 1.3 | 1.3 | 1.3 | 1.3 |
| (G) | G-1 | 0.5 | 0.5 | 0.5 | 0.5 | 0.5 | 0.5 | 0.5 | 0.5 | 0.5 | 0.5 |
| (H) | H-1 | 3.0 | 3.0 | 3.0 | 3.0 | 3.0 | 3.0 | 3.0 | — | — | — |
| | H-2 | 4.0 | 4.0 | 4.0 | 4.0 | 4.0 | 4.0 | 4.0 | — | — | — |
| | H-3 | — | — | — | — | — | — | — | 7.0 | — | — |
| | H-4 | — | — | — | — | — | — | — | — | 7.0 | — |
| | H-5 | — | — | — | — | — | — | — | — | — | 7.0 |

| | | | | | | | | | | |
|---|---|---|---|---|---|---|---|---|---|---|
| Resolution | A | A | A | A | A | A | A | A | A | A |
| Resist shape | A | A | A | A | A | A | A | A | A | A |
| Thermal shock resistance | A | A | A | A | B | A | B | A | A | A |
| Thermal resistance | A | A | A | A | A | A | A | A | A | A |
| Adhesiveness | A | A | A | A | A | A | A | A | A | A |

TABLE 2

| Comparative Example | | 1 | 2 | 3 | 4 | 5 | 6 | 7 |
|---|---|---|---|---|---|---|---|---|
| (A) | A-1 | 21.5 | 21.5 | 21.5 | 21.5 | 21.5 | 21.5 | 21.5 |
| | A-2 | 15.0 | 15.0 | 15.0 | 15.0 | 15.0 | 15.0 | 15.0 |
| (B) | B-1 | 7.0 | 7.0 | 7.0 | 7.0 | 7.0 | 7.0 | 7.0 |
| | B-2 | 3.5 | 3.5 | 3.5 | 3.5 | 3.5 | 3.5 | 3.5 |
| | B-3 | — | — | — | — | — | — | — |
| (C) | C-1 | 0.9 | 0.9 | 0.9 | 0.9 | 0.9 | 0.9 | 0.9 |
| | C-2 | 0.1 | 0.1 | 0.1 | 0.1 | 0.1 | 0.1 | 0.1 |
| | C-3 | 0.1 | 0.1 | 0.1 | 0.1 | 0.1 | 0.1 | 0.1 |
| | C-4 | 0.1 | 0.1 | 0.1 | 0.1 | 0.1 | 0.1 | 0.1 |
| (D) | D-1 | — | — | — | — | — | — | — |
| | D-2 | — | 5.0 | — | 5.0 | 5.0 | 5.0 | 5.0 |
| | D-3 | — | — | — | — | — | — | — |
| | D-4 | 5.0 | — | 5.0 | — | — | — | — |
| (E) | E-1 | 28.0 | 28.0 | 28.0 | 28.0 | 28.0 | 28.0 | 28.0 |
| | E-2 | 10.0 | 10.0 | 10.0 | 10.0 | 10.0 | 10.0 | 10.0 |
| (F) | F-1 | 1.3 | 1.3 | 1.3 | 1.3 | 1.3 | 1.3 | 1.3 |
| (G) | G-1 | 0.5 | 0.5 | 0.5 | 0.5 | 0.5 | 0.5 | 0.5 |
| (H) | H-1 | 3.0 | — | — | — | — | — | — |
| | H-2 | 4.0 | — | — | — | — | — | — |
| | H-6 | — | — | — | 7.0 | — | — | — |
| | H-7 | — | — | — | — | 7.0 | — | — |
| | H-8 | — | — | — | — | — | 7.0 | — |
| | H-9 | — | — | — | — | — | — | 7.0 |

| | | | | | | | |
|---|---|---|---|---|---|---|---|
| Resolution | A | A | A | B | B | B | C |
| Resist shape | A | A | A | B | B | B | B |
| Thermal shock | B | C | C | A | B | A | A |
| resistance | | | | | | | |
| Thermal resistance | B | A | B | A | A | A | A |
| Adhesiveness | B | A | B | A | A | A | A |

### REFERENCE SIGNS LIST

1: photosensitive element, 10: support film, 20: photosensitive layer, 30: protective film.

1. A photosensitive resin composition for a permanent resist, comprising an acid-modified vinyl group-containing resin (A), a thermosetting resin (B), a photopolymerization initiator (C), a photopolymerizable compound (D), and an elastomer (H),
wherein the photopolymerizable compound includes a photopolymerizable compound having an isocyanuric skeleton, and the elastomer includes a liquid elastomer or a granular elastomer having an average particle size of less than 4 μm.

2. The photosensitive resin composition according to claim 1, wherein the photopolymerizable compound having an isocyanuric skeleton is at least one type selected from the group consisting of isocyanuric acid-modified di(meth)acrylate and isocyanuric acid-modified tri(meth)acrylate.

3. The photosensitive resin composition according to claim 1, wherein a content of the photopolymerizable compound is 1 to 15% by mass, on the basis of a total solid content in the photosensitive resin composition.

4. The photosensitive resin composition according to claim 1, wherein the thermosetting resin includes at least one type selected from the group consisting of a bisphenol A-type epoxy resin, a bisphenol F-type epoxy resin, a novolac-type epoxy resin, and an epoxy resin having an isocyanuric skeleton.

5. The photosensitive resin composition according to claim 1, further comprising an inorganic filler (E).

6. The photosensitive resin composition according to claim 1, further comprising an ion scavenger (G).

7. A photosensitive element, comprising a support film and a photosensitive layer formed on the support film,
wherein the photosensitive layer contains the photosensitive resin composition according to claim 1.

8. A printed circuit board, comprising
a permanent resist containing a cured material of the photosensitive resin composition according to claim 1.

9. A method for manufacturing a printed circuit board, comprising:
a step of forming a photosensitive layer on a substrate by using the photosensitive resin composition according to claim 1;
a step of forming a resist pattern by exposing and developing the photosensitive layer; and
a step of forming a permanent resist by curing the resist pattern.

10. A method for manufacturing a printed circuit board, comprising:
a step of forming a photosensitive layer on a substrate by using the photosensitive element according to claim 7;
a step of forming a resist pattern by exposing and developing the photosensitive layer; and
a step of forming a permanent resist by curing the resist pattern.
